(19) United States
(12) Patent Application Publication
(10) Pub. No.: US 2008/0137287 A1
(43) Pub. Date: Jun. 12, 2008

(54) THERMALLY INTEGRATED ELECTRONIC ENCLOSURES

(75) Inventors: Michael Mojaver, La Jolla, CA (US); Andrew Gray, Los Angeles, CA (US)

Correspondence Address: NUTTER MCCLENNEN & FISH LLP, WORLD TRADE CENTER WEST, 155 SEAPORT BOULEVARD, BOSTON, MA, 02210-2604, US

(73) Assignee: Tempest Microsystems, San Diego, CA (US)

(21) Appl. No.: 11/962,809

(22) Filed: Dec. 21, 2007

Related U.S. Application Data
(63) Continuation of application No. 11/145,351, filed on Jun. 3, 2005, now abandoned.
Application No. 11/145,351 is a continuation of application No. 10/939,814, filed on Sep. 13, 2004, now abandoned.
(60) Provisional application No. 60/502,809, filed on Sep. 12, 2003.

(51) Int. Cl. H05K 7/20

(52) U.S. Cl. 361/687; 361/704

(57) ABSTRACT

In one aspect, the present invention provides an enclosure for an electronic device that includes a thermally conductive casing for housing internal components of the device. The casing can include a internal surface for thermal coupling to the internal components and an external surface, thermally coupled to the internal surface, for transmitting heat generated by the internal components to an external environment. In addition, the enclosure can include a heat pipe adapted for having thermal contact with at least one of the internal components at one end therefore and having thermal contact with a portion of the casing's internal surface at another end so as to facilitate transfer of heat generated by that internal component to the external environment.

### RELATED APPLICATION

The present invention claims priority to a United States application entitled “Thermally Integrated Electronic Enclosures,” filed on Sep. 13, 2004 and having a Ser. No. 10/939,814. This parent application is herein incorporated by reference in its entirety.

### FIELD OF THE INVENTION

The present invention relates to enclosures for heat-generating electronic devices, and more particularly, to thermally conductive housings that provide efficient dissipation of heat generated from such electronic devices and their components.

### BACKGROUND OF THE INVENTION

A common problem in the electronics industry is the efficient removal of heat generated by electronic components, especially when these components are confined in small spaces. High heat generating components can create hot spots at certain locations along the outer surface of a casing enclosing the electronic device. These hot spots can potentially increase the risk of damage to the electronic components and their surrounding environment, and even present a risk of injury to a user if inadvertently touched. For these reasons, it is desirable to provide a cooling mechanism for enabling an effective dissipation of heat generated by these electronic components. There is also a need for an improved enclosure for these heat-generating electronic components and devices, which exhibit improved heat flow properties, in order to facilitate thermal conduction and heat removal.

### SUMMARY OF THE INVENTION

The present invention achieves the aforementioned goals by providing an enclosure for an electronic device, such as a computer system, which is configured to dissipate heat that is generated by the electronic device contained within the enclosure. The enclosure comprises a casing for housing internal components of the electronic device. The casing can be formed of an thermally conductive material, such as thermally conductive metallic or non-metallic materials, and can be configured to have thermal contact with one or more of the internal components to facilitate transfer of heat generated by the components to an external environment.

In a related aspect, the casing comprises a heat pipe adapted for thermal contact with at least one of the internal components of the electronic device for transferring heat generated by the component to the external environment. The casing can also be provided with an opening for insertion of a removable disk drive that is configured to engage and thermally contact the casing in order to transfer heat generated by the disk drive to the external environment.

In another aspect, the invention provides an enclosure for a computer system, which includes a casing for enclosing components of the system. The casing is formed of a thermally conductive material and has an internal (inner) surface for thermal coupling to at least one of the components and an external (outer) surface thermally coupled to the internal surface for transmitting heat from the internal surface to an external environment. The enclosure further includes a disk carriage system disposed in the casing for receiving a hard disk such that the hard disk thermally couples to at least a portion of the casing's internal surface upon engaging within the carriage system. A heat pipe, preferably formed of a thermally conductive maternal, is disposed in the casing so as to be in thermal contact at one end thereof with one of the system's components and to be in thermal contact at another end thereof with a portion of the casing's internal surface.

In a related aspect, the heat pipe has a substantially cylindrical shape. In general, the heat pipe can have an elongated structure with any desirable cross-sectional shape, e.g., square, rectangle or ellipse.

In yet another aspect, at least a portion of the casing's external surface includes a corrugated structure, e.g., a plurality of fins, for facilitating heat transfer to the external environment.

Further features of the invention, its nature and various advantages, will be more apparent from the accompanying drawings and the following detailed description of the drawings and various embodiments.

### BRIEF DESCRIPTION OF THE DRAWINGS

FIG. 1 is a perspective view of one embodiment of an enclosure according to the teachings of the present invention;

FIG. 2 is a perspective view of a bottom portion of the enclosure of FIG. 1;

FIG. 3 is a top-down perspective view of the bottom portion of the enclosure of FIG. 1;

FIG. 4 is a side perspective view of the enclosure of FIG. 1;

FIG. 5 is another perspective view of the enclosure of FIG. 1; and

FIG. 6 is a cutaway perspective view of the enclosure of FIG. 5.

### DESCRIPTION OF THE INVENTION

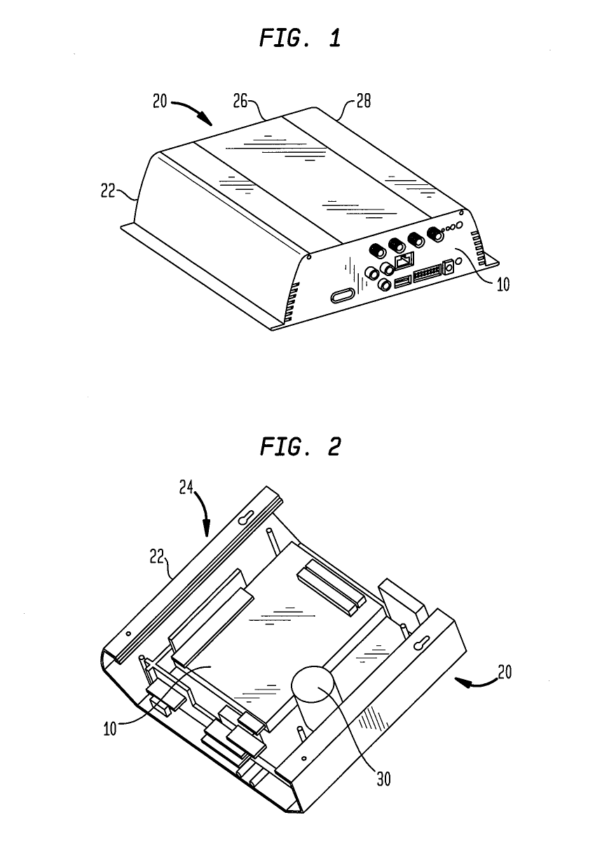

The present invention provides an enclosure for electronic devices that is configured to facilitate dissipation of heat generated by these devices. With reference to FIG. 1, an enclosure 20 according to an exemplary embodiment of the invention provides a housing for various internal components of an electronic device 10. Without any loss of generality, and for the purpose of describing the invention with more clarity, the electronic device 10 is assumed to be a computer. Those having ordinary skill in the art will, however, appreciate that the teachings of the invention can be applied to electronic devices other than computers. The enclosure 20 includes a casing 22 that functions not only as a portion of the enclosure but also as a heat sink for removing heat from various components and/or subsystems of the computer 10. For example, as described in more detail below, the casing 22 can be in thermal contact with the computer's processor, disk drive, or other subsystems that generate heat during the computer's operation to extract the generated heat and transfer it to the surrounding environment. More particularly, an outer surface 26 of the casing 22 is exposed to the ambient environment while an inner surface 24 (or a portion thereof) of the casing (a surface opposed to the outer surface) can be in thermal contact with selected internal components of the computer 10. In this manner, the casing 22 transfers heat from the inner components to the ambient environment. A corrugated structure 28, for example, in the form of a plurality of fins, can be provided on the casing's outer surface to facilitate heat transfer to the surrounding environment.

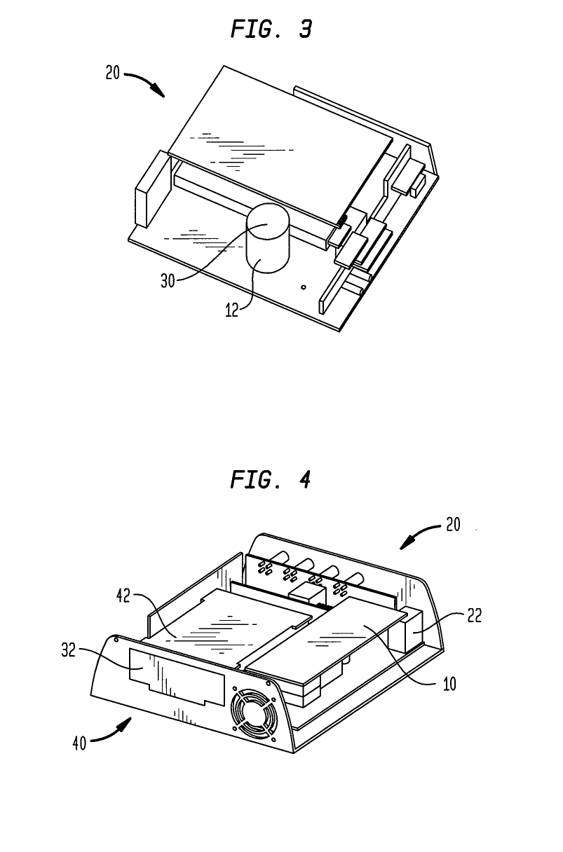

With reference to FIG. 2, in this exemplary embodiment, the casing 22 also includes a heat pipe 30, in the form of a cylindrical structure, that can be in thermal contact with one or more selected internal components of the computer 10. For example, as shown more clearly in FIG. 3, in this exemplary embodiment, the heat pipe 30 is in thermal contact with a processor 12 of the computer 10 to transfer heat generated by the processor 12 to the outside environment via the casing's outer surface 24 (see FIG. 1). Although the thermal contact between the heat pipe 30 and the processor 12 is preferably achieved by providing direct contact between them, in an alternative embodiment, the heat pipe 30 can be disposed in close proximity of the processor 12 to allow flow of heat from the processor 12 to the heat pipe 30. The heat pipe 30 is preferably formed of a material that exhibits good thermal conductivity, such as copper. Further, the heat pipe 30 and the remainder of the casing 22 can be formed as a unitary structure, or alternatively, they can be formed separately and joined together.

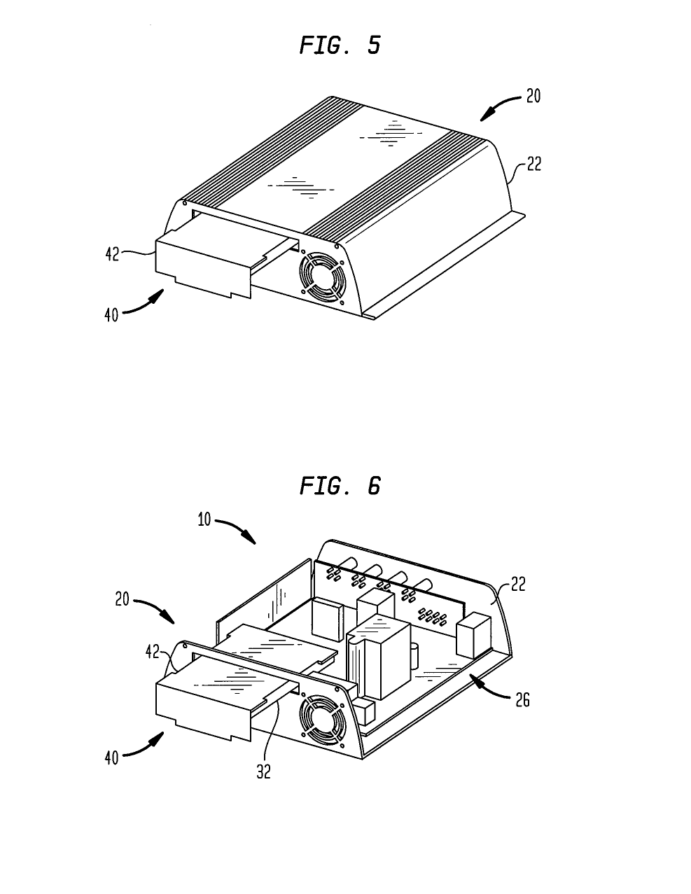

In another aspect, the invention provides a disk carriage system 40 (FIG. 4) that allows a hard disk 42 of the computer system to be in thermal contact with the casing 22, and further allows easy insertion or removal of the disk 42 into or out of the computer 10. By way of example, with reference to FIGS. 4, 5 and 6, the computer casing 22 can include an opening 32 through which a disk 42 can be inserted into or removed from the computer 10. As shown in FIGS. 5 and 6, a slider mechanism can be utilized for insertion or removal of the disk 42. When the disk 42 is disposed within the computer system 10, a portion of the disk 42 remains in thermal contact with the casing 22. This advantageously allows heat conduction from the disk 42 to the casing 22 for removal to the surrounding environment.

One of ordinary skill in the art will appreciate further features and advantages of the invention based on the above-described embodiments. Accordingly, the invention is not to be limited by what has been particularly shown and described, except as indicated by tie appended claims.

What is claimed is:

1. An enclosure for an electronic device, comprising
a casing for housing internal components of said device, said casing being formed of an electrically conductive material and having thermal contact with one or more of said internal components to facilitate transfer of heat generated by said components to an external environment.

2. The enclosure of claim 1, wherein said casing comprises a heat pipe adapted for having thermal contact with at least one of said internal components for transferring heat generated by said component to the external environment.

3. The enclosure of claim 1, wherein said electronic device comprises a computer.

4. The enclosure of claim 3, further comprising an opening for receiving a removable disk drive.

5. The enclosure of claim 4, wherein the enclosure is configured to engage and thermally contact the disk drive when placed inside the opening.

6. The enclosure of claim 2, wherein said heat pipe is formed of a thermally conductive material,

7. The enclosure of claim 6, wherein said thermally conductive material comprises copper.

8. An enclosure for a computer system, comprising
a casing for enclosing components of said system, said casing being formed of a thermally conducting material and having an internal surface for thermal coupling to at least one of said components and an external surface thermally coupled to said internal surface for transmitting heat from said internal surface to an external environment
a disk carriage system disposed in said casing for receiving a hard disk, said hard disk thermally coupling to at least a portion of said internal surface upon engaging within said carriage system,
a heat pipe disposed in said casing so as to be in thermal contact at one end thereof with one of said components and at another end with a portion of said internal surface.

9. The enclosure of claim 8, wherein said heat pipe has a substantially cylindrical shape.

10. The enclosure of claim 8, wherein said heat pipe is formed of a thermally conductive material.

11. The enclosure of claim 10, wherein said heat pipe is formed of copper.

12. The enclosure of claim 8, wherein said heat pipe forms a unitary structure with said casing.

13. The enclosure of claim 8, wherein at least a portion of the casing's external surface comprises a corrugated structure for facilitating heat transfer to an external environment.

14. The enclosure of claim 13, wherein said corrugated structure comprises a plurality of fins.

15. The enclosure of claim 8, further comprising a slider mechanism for introducing the hard disk into the disk carriage system and removing the hard disk therefrom.

16. The enclosure of claim 8, wherein one of the components of the computer system comprises a processor and where in said heat pipe is in thermal contact at one end thereof with said processor.
